(19) United States
(12) Patent Application Publication
(10) Pub. No.: US 2008/0174353 A1
(43) Pub. Date: Jul. 24, 2008

(54) PATH DELAY ADJUSTMENT CIRCUITRY USING PROGRAMMABLE DRIVER

(76) Inventors: John Thomas Badar, Austin, TX (US); KM Mozammel Hossain, Austin, TX (US); John Mack Isakson, Austin, TX (US)

Correspondence Address: IBM CORP (YA);C/O YEE & ASSOCIATES PC, P.O. BOX 802333, DALLAS, TX, 75380, US

(21) Appl. No.: 11/624,605

(22) Filed: Jan. 18, 2007

(51) Int. Cl. H03H 11/26

(52) U.S. Cl. 327/276

(57) ABSTRACT

A method and system for using a programmable driver to dynamically adjust the path delay of a circuit. The path delay adjustment circuit in the illustrative embodiments comprises two or more latches, wherein each latch receives a signal, processes the signal, and generates an output. Compare logic connected to the latches compares the outputs to determine whether the outputs are equal. A counter connected to the compare logic increments a present state of code within the counter if the compare logic determines that the outputs are not equal. A controller connected to the counter comprises a decoder which receives the incremented code from the counter and converts the incremented code to thermometer code. The controller uses the thermometer code to adjust the drive strength of a driver of at least one of the signals.

### BACKGROUND

1. Field of the Invention

The present invention relates generally to enhancing performance in a data processing system, and in particular, to a method and system for dynamically adjusting the path delay of a circuit using a programmable driver.

2. Description of the Related Art

A microprocessor is a silicon chip that contains a central processing unit (CPU) which controls all the other parts of a digital device. Designs vary widely, but in general, the CPU consists of a control unit (or decoder), an arithmetic and logic unit (ALU) and memory (registers, cache, RAM and ROM) as well as various temporary buffers and other logic. The control unit fetches instructions from memory and decodes them to produce signals which control the other part of the computer. This may cause the control unit to transfer data between memory and ALU or to activate peripherals to perform input or output. A parallel computer has several CPUs which may share other resources, such as memory and peripherals. In addition to bandwidth (the number of bits processed in a single instruction) and clock speed (how many instructions per second the microprocessor can execute), microprocessors classifications include either RISC (reduced instruction set computer) or CISC (complex instruction set computer).

An oscillator clock is a circuit within a microprocessor that creates a series of pulses that pace the microprocessor's electronic system. The oscillator clock synchronizes, paces, and coordinates the operations of the microprocessor's circuit.

Path delay elements with the microprocessor perform the function of delaying a signal in accordance with a control signal. For proper functioning of synchronous circuits, it is important for data to arrive at the right time relative to a clock signal. Due to process, voltage, and temperature (PVT) variations and other design constraints, data arrival may not always occur at the desired time. The use of digital delay lines compensates for variations in design and fabrication. Digital delay lines provide a mechanism for adding a set amount of delay into the receipt of a signal to allow two or more signals to be synchronized (i.e., arrive approximately at the same time).

### SUMMARY

The illustrative embodiments provide a method and system for using a programmable driver to dynamically adjust the path delay of a circuit. The path delay adjustment circuit in the illustrative embodiments comprises two or more latches, wherein each latch receives a signal, processes the signal, and generates an output. Compare logic connected to the latches compares the outputs to determine whether the outputs are equal. A counter connected to the compare logic increments a present state of code within the counter if the compare logic determines that the outputs are not equal. A controller connected to the counter comprises a decoder which receives the incremented code from the counter and converts the incremented code to thermometer code. The controller uses the thermometer code to adjust the drive strength of a driver of at least one of the signals.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a circuit diagram of an exemplary wire delay adjust network for critical signals in accordance with the illustrative embodiments;

FIG. 2 is an example conversion of incremented code to thermometer code in accordance with the illustrative embodiments;

FIG. 3 is a diagram illustrating simulation results of implementing wire delay adjustments in accordance with the illustrative embodiments; and

FIG. 4 is a flowchart of a process for dynamically adjusting the path delay of a circuit using a programmable driver in accordance with the illustrative embodiments.

### DETAILED DESCRIPTION OF THE PREFERRED EMBODIMENT

The illustrative embodiments provide a method and system for dynamically adjusting the path delay of a circuit using a programmable driver. In particular, the proposed circuits in the illustrative embodiments comprise a fine tune element which allows for adjusting the delay of the critical path to accommodate higher data transfer speeds and to correct timing failures. The critical path is the slowest path in the circuit. The fine tune element includes a programmable driver with associated logics which controls the delay of the critical signal in order to meet timing requirements for the circuit. The timing requirements will include synchronization requirements, which require that a signal arrive at a point in the circuit at the same time as one or more other signals.

The fine tune element in the proposed circuits comprises logic which determines if there is a timing failure (e.g., synchronization failure, etc.) in the circuit. If a timing failure is detected, the fine tune element dynamically changes the drive strength of the driver. Changing the drive strength of the driver enables adjustment of the delay circuits inserted in the clock paths of the reference signals to meet the timing requirements of the circuit. The process described in the illustrative embodiments provides an advantage over other delay adjustment techniques since the dynamic changes provided in the illustrative embodiments allow for increased granularity of path delay adjustment. These changes may include increases or decreases in drive strength that are finer than one gate delay. Gate delay, or propagation delay, is the amount of time starting from when the input to a logic gate becomes stable and valid, to the time that the output of that logic gate is stable and valid. Implementation of the proposed circuits may occur in any location on the chip and on any net to accommodate process, voltage, and temperature (PVT) variations.

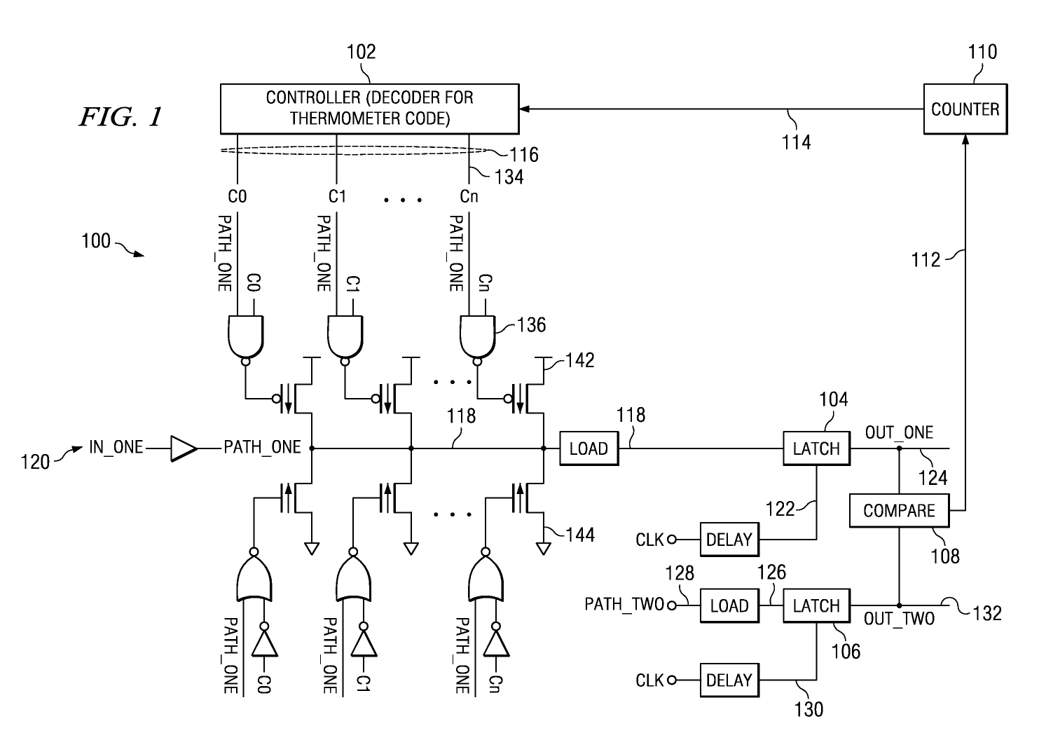

FIG. 1 is a circuit diagram of an exemplary wire delay adjustment network for critical signals in accordance with the illustrative embodiments. In this illustrative example, circuit 100 enables control of the delay of a critical signal by adjusting the drive strength of the driver in increments finer than one gate delay. Circuit 100 comprises controller 102, capture latches 104 and 106, compare logic 108, counter 110, and a single feedback path for automatically setting the controller.

The single feedback path comprises compare output path 112 which provides a result of the comparison between the reference signals to a counter, and counter output path 114 which provides incremented code signals to the decoder. Control signals 116 comprise thermometer code which controls the drivers to increase or decrease the drive strength of the circuit. During normal operation, circuit 100 may generate reference signals locally and may require these signals to be synchronized with one another.

Capture latches 104 and 106 are logic circuits which store one or more bits. A latch has a data input, a clock input, and an output. For instance, upon receiving a signal comprising data input 118 on In_One 120 path and clock signal input 122, capture latch 104 stores the data on input and transfers the data to output as out_one 124. Likewise, capture latch 106 receives a signal comprising data input 126 on Path_Two 128, and clock signal input 130 stores the data on input and transfers the data to output as out_two 132. Capture latches 104 and 106 provide their output (out_one 124 and out_two 132, respectively) to compare logic 108.

Compare logic 108 samples the data in the latch outputs. One example of a simple compare logic is a logic gate, such as an exclusive-OR (XOR) gate. A logic gate performs a logical operation on one or more logic inputs and produces a single logic output. Compare logic 108 receives two inputs and produces a true value only when the two input values are different (i.e., a miscompare). Compare logic 108 produces a false value if the inputs are equal or within an acceptable range of logic 1 and logic 0. For example, a miscompare may occur when a timing critical path fails due to set-up violations. Thus, when compare logic 108 receives latch outputs out_one 124 and out_two 132 from capture latches 104 and 106, compare logic 108 processes the latch outputs to generate either a true value if out_one 124 latch output and out_two 132 latch output are different, and a false value if out_one 124 latch output and out_two 132 latch output are the same. If there is a miscompare of the latch outputs, compare logic 108 provides the compare result to counter 110.

Counter 110 is a device which stores the number of times a particular event has occurred. In this illustrative example, counter 110 counts in binary coded decimal (BCD). Binary coded decimal is an encoding for decimal numbers in which each digit is represented by its own binary sequence. Upon receiving a signal from compare logic 108, counter 110 increments the present state of BCD code within counter 110 to the next state for the BCD signal. Counter 110 then provides the incremented BCD signal to controller 102.

Controller 102 comprises a decoder which receives the BCD signal and converts the signal into thermometer code. Thermometer code is well known in the art and comprises code which changes the control bits up or down one bit at a time. A change occurs to a control bit which is adjacent to the previously changed control bit (i.e., changes may be made to adjacent bits either from left to right or right to left). The decoder converts BCD code into thermometer code since the use of thermometer code will prevent a tri-state of the signal logic levels while the chip is operating. For instance, the far right control signal (Cn) 134 of the thermometer code always comprises a value of “1”, which prevents the driver of a critical signal from being tri-stated. A tri-state occurs when the logic level of a signal generated by the driver is neither logic 0 nor logic 1. A signal in tri-state is undesirable because down stream logic may malfunction without a valid logic level (e.g., 0 or 1).

Controller 102 may then use thermometer code to generate control signals to increase the drive strength of the driver in an iterative process until the timing of the critical signal is met. For example, the drive strength may be increased iteratively in response to a determination by the compare logic that a timing failure still exists. The control signals turn ON one gate of the driver at a time (e.g., control signal (Cn) 134 first turns on gate 136, control signal (Cn-1) then turns on its respective gate, etc.), thereby enabling the driver to drive any load by incrementally supplying more current to the load using additional Positive channel field effect transistor (PFET) and Negative channel field effect transistor (NFET) devices attached to the critical net, such as, for example, PFET 142 or NFET 144. To increment the drive strength in each iteration, the controller turns ON the next adjacent control signal, such as turning ON the next left control signal (e.g., (Cn-1)) from control signal (Cn) 134. Adjacent control signals may subsequently be turned ON as necessary to meet the timing requirements of the critical net. The thermometer code may perform the same function by implementing the changes to adjacent control bits in a right to left manner or from a left to right manner.

The illustrative embodiments provide the ability to improve any timing path in the circuit with very fine tuning. In one embodiment, the control signals generated by the controller comprise a wide timing window, such as, for example, in the range of 50 picoseconds (ps) to 80 ps. The controller also may increase or decrease the control signals by small increments, such as, for example, 8 ps, which is less than one fan-out-of-four (FO4) value or less than a single gate delay. Thus, with the fine tune element in the illustrative embodiments, a developer may design the circuit at tighter tolerances. Fan-out is the number of logic gates that are driven by any driving gate. For example, if one inverter drives five NAND gates, the fan-out value is “5”. FO4 is the fan-out-of-four when the driver and the loads are identical (e.g., when 1 NAND gate is driving 4 similar NAND gates, the FO4 is 4). Generally, the fan-out gate delays limit the design of a circuit. In other words, designers may not design a circuit which has less delay in the logic gates than the fan-out gate delays. The granularity provided in the path delay adjustment in the illustrative embodiments is very fine, thereby allowing the circuit to be fine tuned with less delay than the fan-out gate delays. Thus, the controller may change the control signals in increments finer than one gate delay. Each increment of the control signal may tune even lower (e.g., less than 8 ps) if necessary.

Although a particular logic gate configuration is shown in FIG. 1, it would be apparent to one of ordinary skill in the art that different logical gates may be implemented in the circuit and still perform the same fine tuned gate delay adjustment as described in FIG. 1.

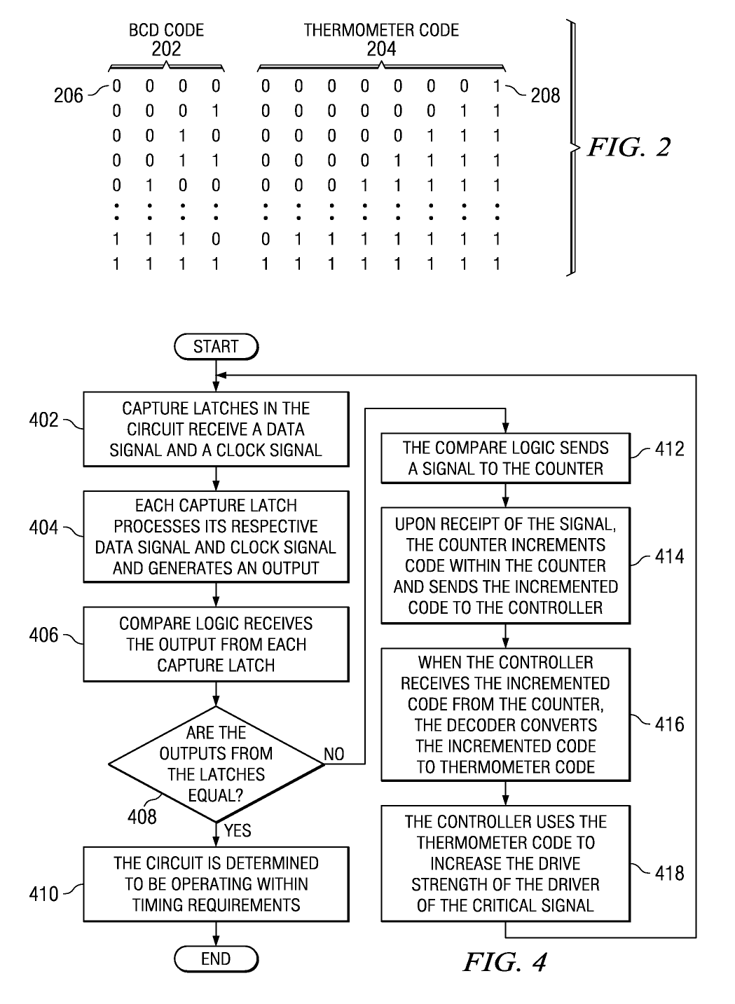

FIG. 2 is an example conversion of incremented code to thermometer code in accordance with the illustrative embodiments. It is advantageous for the circuit controller, such as controller 102 in FIG. 1, to convert the incremented code (in this case, BCD code) to thermometer code because if the controller uses the BCD code during the fine tuning of the driver strength, the critical signal may be on tri-state. For instance, a tri-state may occur if the BCD code used to increment the driver strength is fine tuned from 0111 to 1000.

The circuit controller performs the conversion of BCD code 202 to thermometer code 204 in response to a failure of the critical path timing. When comparison logic, such as compare logic 108 in FIG. 1, detects a miscompare on the latch outputs, the comparison logic sends a BCD signal to the circuit controller. The circuit controller takes the BCD signal and converts the BCD code into thermometer code. For instance, as shown in the example conversion in FIG. 2, BCD code 0000 206 converts into thermometer code 00000001 208, etc. The circuit controller then uses the thermometer code to generate control signals to control and fine tune the strength of the drivers, essentially increasing or decreasing the drive strength of the driver until the timing required by the circuit for the critical signal is met.

FIG. 3 is a diagram illustrating simulation results of implementing wire delay adjustments in accordance with the illustrative embodiments. In particular, FIG. 3 illustrates the results of adjusting the drive strength of the driver by using the thermometer code to incrementally turn on control signals, such as control signal 134 in FIG. 1. In these example simulation results, the increment granularity of path delay adjustment is 8 ps, although the illustrative embodiments allows for using other (including lower) increments.

The simulation allows one to observe the latch output signals to determine whether the output signals arrive at the compare logic at the same time. Specifically, INPUT1 302 is the signal applied to In_One 120 and Path_Two 128 in FIG. 1. The latch output signals, such as Out_One 124 and Out_Two 132 in FIG. 1, may have separate, similar inputs. However, the latch outputs may arrive at compare logic 108 in FIG. 1 at different times. These simulation results show how the strength of the driver is fine tuned in such a way that the latch output signals will arrive at compare logic 108 in FIG. 1 at the same time.

RCV_IN1 304 and RCV_IN 306 are the respective inputs to capture latches 106 and 104 in FIG. 1. As the simulation shows, RCV_IN 306 initially does not match the timing of RCV_IN1 304. Thus, the controller generates control signals to increase the drive strength of the driver to speed up the arrival time of RCV_IN 306 at capture latch 104 in FIG. 1. Control signals CNTL_LINE_0 through CNTL_LINE_7 are representative of control signals C0 through Cn 116 in FIG. 1. In this example, CNTL_LINE_7 308 represents control signal Cn 134 in FIG. 1. As previously mentioned, since control signal Cn 134 in FIG. 1 is always ON since it is the right most signal on the thermometer code, CNTL_LINE_7 308 is not switching in FIG. 3. The controller may switch the next control signal adjacent to Cn 134 in FIG. 1 on (i.e., control signal Cn-1), shown as CNTL_LINE_6 310 in FIG. 3, which increases the drive strength in one increment. If RCV_IN 306 still does not match the timing of RCV_IN1 304, the controller turns on the control signal adjacent to CNTL_LINE_6 310 (i.e., CNTL_LINE_5 312) to increase the drive strength another increment. As shown, the controller incrementally turns on control signals CNTL_LINE_6 310 to CNTL_LINE_0 314 one by one to fine tune the drive strength of the driver. The simulation results show that after turning on CNTL_LINE_0 314, the simulation shows that RCV_IN 306 now matches the timing of RCV_IN1 304.

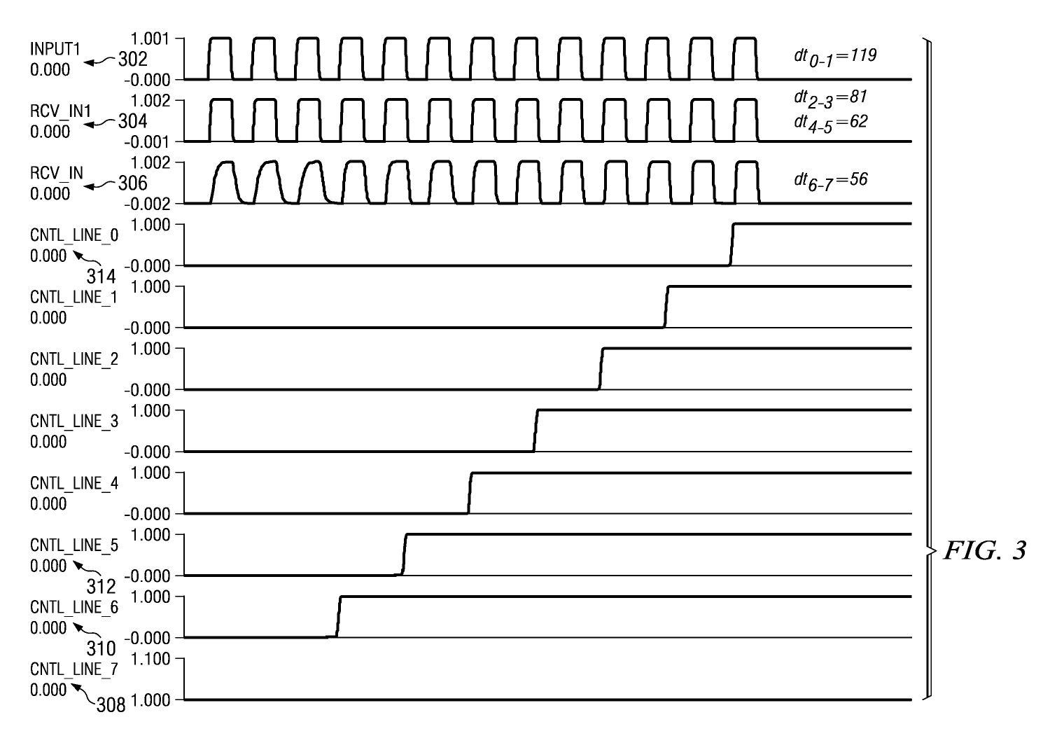

FIG. 4 is a flowchart of a process for dynamically adjusting the path delay of a circuit using a programmable driver in accordance with the illustrative embodiments. The process begins when latches in the circuit receive a data signal and a clock signal (step 402). Each capture latch processes its respective data signal and clock signal and generates an output (step 404). Compare logic receives the output from each capture latch (step 406). Compare logic determines whether the outputs from the latches are equal (step 408). If the outputs are equal (‘yes’ output of step 408), then the circuit is determined to be operating within timing requirements (step 410), and the process terminates thereafter.

If the outputs are not equal (‘no’ output of step 408), then the compare logic sends a signal to the counter (step 412). Upon receipt of the signal, the counter increments code within the counter and sends the incremented code to the controller (step 414). When the controller receives the incremented code from the counter, the decoder converts the incremented code to thermometer code (step 416). The thermometer code generates a control signal which increases the drive strength of the driver of the critical signal (step 418). This process loops back to step 402 in an iterative manner to generate additional control signals and incrementally increase the drive strength of the driver until the timing of the critical signal is met (i.e., ‘yes’ output at step 408).

It should be noted that the path delay adjustment process described in FIG. 4 may also be implemented in reverse to decrease the drive strength of the driver. Thus, if the compare logic determines that a signal arrives too early in accordance with the timing requirements of the circuit, the controller may decrease the drive strength of the driver in order to slow down the driver until the timing of the signal is met.

The circuit as described above is part of the design for an integrated circuit chip. The chip design is created in a graphical computer programming language and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A computer implemented method for dynamically adjusting a path delay of a circuit, the computer implemented method comprising:
receiving a first signal at a latch in the circuit, wherein the latch processes the first signal and generates a first output;
comparing the first output of the latch against a second output from a second latch to determine whether the first output and the second output are equal;
if the first output and the second output are equal, the circuit is determined to be operating within timing requirements of the circuit; otherwise,
sending a second signal to a counter in the circuit, wherein the counter increments a present state of code within the counter; and
providing the incremented code to a controller in the circuit, wherein a decoder in the controller converts the incremented code to thermometer code, and wherein the thermometer code generates control signals to adjust a drive strength of a circuit driver of the first signal.

2. The computer implemented method of claim 1, wherein the receiving, comparing, sending, and providing steps are repeated until the first output and the second output are equal.

3. The computer implemented method of claim 1, wherein the comparing step is performed using compare logic in the circuit.

4. The computer implemented method of claim 1, wherein the counter increments the present state of code to a next state.

5. The computer implemented method of claim 1, wherein adjusting the drive strength includes increasing or decreasing the drive strength of the circuit driver.

6. The computer implemented method of claim 1, wherein adjusting the drive strength further comprises:
incrementally supplying more current to the first signal.

7. The computer implemented method of claim 6, wherein incrementally supplying more current to the first signal is performed using Positive channel field effect transistors or Negative channel field effect transistors attached to the first signal.

8. The computer implemented method of claim 1, wherein the control signals adjust the drive strength in increments less than a single gate delay.

9. The computer implemented method of claim 1, wherein the decoder converts the incremented code to thermometer code to prevent a tri-state of signal logic levels while the circuit is operating.

10. The computer implemented method of claim 1, wherein the thermometer code generates the control signals by changing control bits on or off one bit at a time.

11. The computer implemented method of claim 10, wherein changing control bits on or off one bit at a time turns on or off one gate of the circuit driver at a time.

12. A path delay adjustment circuit, comprising:
a plurality latches, wherein each latch in the plurality receives a signal, processes the signal, and generates an output;
compare logic connected to the plurality of latches for comparing the output from each latch to determine whether the outputs are equal;
a counter connected to the compare logic, wherein the counter increments a present state of code within the counter if the compare logic determines that the outputs are not equal;
a controller connected to the counter, wherein the controller comprises a decoder, and where the decoder receives the incremented code from the counter and converts the incremented code to thermometer code; and
a circuit driver connected to the controller, wherein the controller uses the thermometer code to adjust a drive strength of the circuit driver of at least one of the signals.

13. The path delay adjustment circuit of claim 12, wherein the counter increments the present state of code to a next state.

14. The path delay adjustment circuit of claim 12, wherein the thermometer code increases or decreases the drive strength of the circuit driver.

15. The path delay adjustment circuit of claim 12, wherein the thermometer code adjusts the drive strength by incrementally supplying more current to at least one of the signals until the outputs are equal.

16. The path delay adjustment circuit of claim 15, wherein the thermometer code incrementally supplies more current to at least one of the signals using Positive channel field effect transistors or Negative channel field effect transistors attached to at least one of the signals.

17. The path delay adjustment circuit of claim 12, wherein the thermometer code adjusts the drive strength in increments less than a single gate delay.

18. The path delay adjustment circuit of claim 12, wherein the decoder converts the incremented code to thermometer code to prevent a tri-state of signal logic levels while the path delay adjustment circuit is operating.

19. The path delay adjustment circuit of claim 12, wherein the thermometer code generates control signals which adjust the drive strength by changing control bits on or off one bit at a time.

20. The path delay adjustment circuit of claim 19, wherein the control bits are changed on or off one bit at a time to turn on or off one gate of the circuit driver at a time.
